(19) United States
(12) Patent Application Publication
(10) Pub. No.: US 2001/0022941 A1
(43) Pub. Date: Sep. 20, 2001

(54) TURBO MOLECULAR PUMP

(76) Inventor: YASUSHI MAEJIMA, NARASHINO-SHI (JP)

Correspondence Address: ADAMS & WILKS, 50 BROADWAY, 31ST FLOOR, NEW YORK, NY, 10004

(21) Appl. No.: 09/128,712

(22) Filed: Aug. 4, 1998

(51) Int. Cl. F04B 17/00; F04B 35/04; C23C 16/00

(52) U.S. Cl. 417/423.4; 118/715; 415/90

(57) ABSTRACT

A turbo molecular pump which can prevent the lowering in vacuum property while maintaining the increased throughput of the gas to be discharged during a normal operation. An axial interval between a rotor vane and a stator vane provided close to a inlet port is set so that the gas can be dealt as molecular flow under a condition that the pressure in the inlet port during the normal operation is not less than 10 mTorr. Since whether or not the gas can be dealt as the molecular flow is delimited by a mean free path of gas molecular, the above axial interval is set based on the mean free path. With this arrangement, the gas can be dealt as the molecular flow under the condition of pressure not less than 10 mTorr during the normal operation, and thus sufficient discharge performance can be obtained. Consequently, even if the throughput of the gas supplied to a vacuum chamber during the normal operation is increased, it is possible to ensure the required pressure (vacuum property) while maintaining the increased throughput.

### BACKGROUND OF THE INVENTION

1. Field of the Invention

The present invention relates to a turbo molecular pump used, for instance, as a vacuum device for a semiconductor manufacturing apparatus.

2. Description of Related Art

A turbo molecular pump is designed such that rotor vanes attached to a rotor shaft rotating at high velocity and stator vanes fixed by an outer casing are alternately arranged so that a pair of the rotor vane and the stator vanes are arranged in multi-stages in an axial direction of the rotor axis. The rotor vanes include a plurality of blades each inclined at a predetermined angle. The stator vane includes a plurality of blades similarly to the rotor vane, and the inclined direction of each blade is opposite from the inclined direction of the blade provided in the rotor vane.

An axial interval between the rotor vane and the stator vane is determined from a viewpoint of convenience in design and so on. For example, the axial interval between the rotor vane and the stator vane located close to a inlet port is set to about 5 mm.

In the turbo molecular pump thus constructed, the rotor vanes are rotated by the rotation of the rotor shaft, and the gas molecular is beaten in the rotating direction so that the blades of rotor vanes are moved axially, thereby carrying out the discharge of the gas.

The turbo molecular pump of this type is used, for instance, for the purpose of the discharge for a vacuum chamber of the semiconductor manufacturing apparatus. That is, in order to carry out processing of the semiconductor in the vacuum chamber, it is necessary to always supply gas to the vacuum chamber, and discharge the gas supplied thereto by the turbo molecular pump.

However, recent tendency is directed toward the increase in gas amount to be supplied to the vacuum chamber, and also, the gas amount to be discharged by the turbo molecular pump in a normal operation is increasing.

A test in throughput characteristic was conducted to confirm whether or not a conventional turbo molecular pump can provide sufficient vacuum property (discharge performance) in case where the amount of the gas to be discharged therefrom is increased. The test result is shown by one-dotted chain line A in FIG. 4.

Here, the gas to be discharged was nitrogen (N₂), and a dry pump of 1300(l/min) was used as an auxiliary pump.

From the test result, it was found that the sufficient vacuum property was obtained (for example, the pressure of not more than 10⁻² Torr, i.e. 10 m Torr was obtained) in the case where the throughput of the gas to be discharged was small, but the sufficient vacuum property could not be obtained (for example, the pressure was larger than 10 mTorr) in the case where the throughput of the gas to be discharged was large.

Based on this result, the present inventor has made the detailed study to seek a cause or reason why the sufficient vacuum property could not be obtained in the case where the throughput of the gas was large, and discovered and obtained a novel view that the lowered discharge performance was caused by a fact that the discharged gas did not form molecular flow in an axial space between the rotor vanes and stator vanes near the inlet port of the turbo molecular pump. In other words, the present inventor has obtained such a novel view that the lowering in the vacuum property in association with the increased throughput of the gas was closely related to the axial interval between the rotor vanes and the stator vanes.

### SUMMARY OF THE INVENTION

The present invention was made on the basis of the above-described novel view, and an object of the present invention is to provide a turbo molecular pump capable of ensuring the sufficient vacuum property while maintaining the increased throughput of the gas even when the throughput of the gas to be discharged in a normal operation is increased.

To attain the above-described object, a turbo molecular pump according to the present invention is characterized by comprising:

a rotor shaft;

a bearing for rotatably supporting the rotor shaft;

a motor for rotating the rotor shaft supported by the bearing;

rotor vanes of multiple stages provided to the rotor shaft; and

stator vanes of multiple stages arranged between the rotor vanes of multiple stages, respectively, and

that an axial interval between at least one of the rotor vanes and a corresponding one of the stator vane is set to a value by which a gas can be dealt as a molecular flow under a condition of pressure not less than 10 mTorr during a normal operation.

The present invention can be also expressed as follows:

That is, a turbo molecular pump according to the present invention is characterized by comprising:

a rotor shaft;

a bearing for rotatably supporting the rotor shaft;

a motor for rotating the rotor shaft supported by the bearing;

rotor vanes of multiple stages provided to the rotor shaft; and

stator vanes of multiple stages arranged between the rotor vanes of multiple stages, respectively, and

that at least one axial interval between one of the rotor vanes and a corresponding one of the stator vane is set to a value by which a gas can be dealt as a molecular flow under a condition that a discharge throughput during a normal operation is not less than 1000 SCCM.

The one of rotor vane is located closest to a inlet port among the rotor vanes of multiple stages, and the corresponding one of the stator vane is located closest to the inlet port among the stator vanes of multiple stages.

The at least one axial interval between one of the rotor vanes and a corresponding one of the stator vane is set based on a mean free path of molecular gas.

As described above, according to the present invention, the axial interval between the stator vane and the rotor vane is set to such a value as to be capable of dealing with the gas as the molecular flow under the condition that the pressure in the inlet port is equal to or more than 10 mTorr during the normal operation.

Therefore, according to the present invention, the gas can be dealt as the molecular flow under the condition that the pressure is equal to or more than 10 mTorr during the normal operation, and sufficient discharge performance can be obtained. Thus, even if the throughput of the gas supplied to the vacuum chamber during the normal operation is increased compared with the conventional one, the present invention can ensure the required pressure (required vacuum property) while maintaining the increased throughput of the gas.

### BRIEF DESCRIPTION OF THE DRAWINGS

In the accompanying drawings:

FIG. 1 is a sectional view showing major parts of a turbo molecular pump for explanation about a basic thought of the present invention;

FIG. 2 is a developed view of a rotor vane and a stator vane to show the major parts;

FIG. 3 is a sectional view showing the turbo molecular pump according to an embodiment of the present invention; and

FIG. 4 shows a result of a throughput characteristic test carried out on the embodiment of the present invention and a conventional apparatus.

### DETAILED DESCRIPTION OF THE PREFERRED EMBODIMENT

The basic thought of the present invention is described hereafter, prior to the description regarding an embodiment of the present invention.

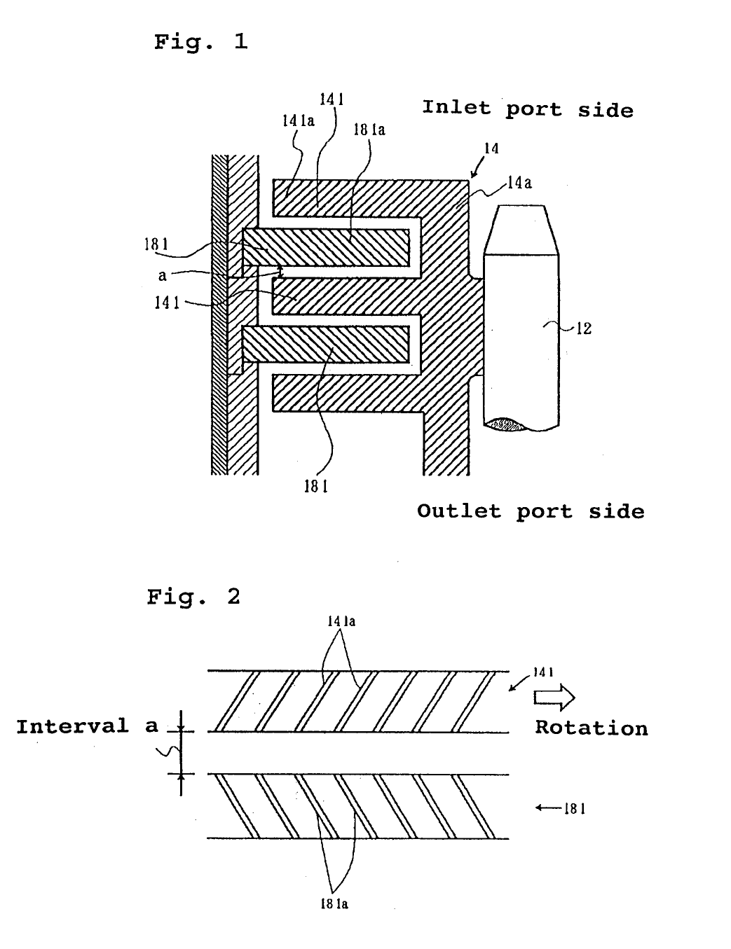

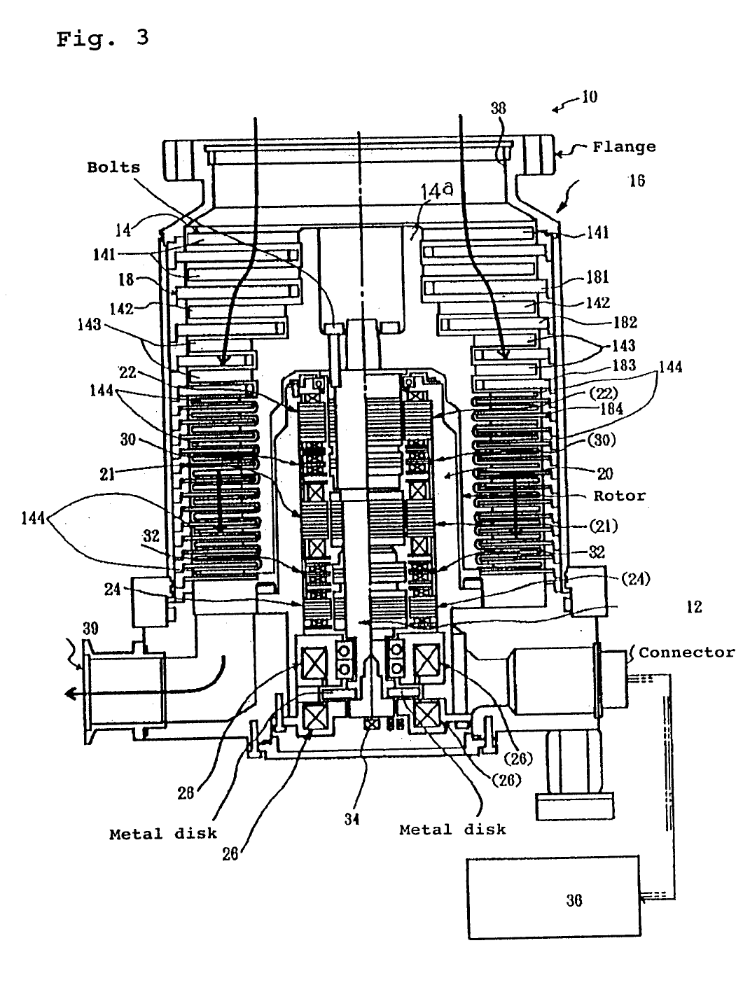

FIG. 1 is a sectional view showing major parts of the present invention with other parts omitted to simplify the explanation about the basic thought of the present invention. FIG. 2 is a developed view showing a relationship between a rotor vane 141 and a stator vane 181.

The present invention has been based on the above-described novel view, and as shown in FIG. 1 an axial interval a between the rotor vane 141 and the stator vane 181 at least closest to a inlet port is set to such a value as to deal with gas as molecular flow under a condition that the pressure in the inlet port during the normal operation is not less than 10 mTorr.

In case where the turbo molecular pump is used to discharge gas supplied to a vacuum chamber during the normal operation, the throught put of the gas to be discharged is predetermined. Therefore, the turbo molecular pump must satisfy a condition required by that predetermined discharge throughput during the normal operation and must provide vacuum property (for example, pressure of not more than 20 mTorr) concurrently needed. Accordingly, the present invention can be expressed as follows: That is, the axial interval a between the rotor vane 141 and the stator vane 181 at least closest to the inlet port is set to such a value as to deal with gas as the molecular flow under a condition that the discharge throughput during the normal operation is not less than 1000 SCCM.

Next, a method of setting in detail the axial interval a, for example, between the rotor vane 141 and the stator vane 181 on the basis of the above-described thought is described hereafter.

As described above, whether or not the gas can be dealt as the molecular flow in the axial interval between the rotor vane 141 and the stator vane 181 depends on a mean free path of the gaseous molecular. This mean free path λ is expressed approximately by the following formula (1):

λ=0.05/pressure (mm) (1)

Here, the unit for the pressure in the formula (1) is Torr.

If the mean free path λ is not less than the above-described interval a, the gas can be dealt as the molecular flow.

Next, a case where the gas is dealt as the molecular flow under a condition that the pressure is not more than 20 mTorr during the normal operation is described.

From the formula (1), the mean free path λ under the condition that the pressure is 20 mTorr is 2.5 mm (λ=2.5 mm).

Therefore, if the axial interval a between the rotor vane 141 and the stator vane 181 is set to not more than 2.5 mm, then the gas can be dealt as the molecular flow under the condition of pressure of not more than 20 mTorr.

In addition, an axial interval between a rotor vane 142 and a stator vane 182, an axial interval between a rotor vane 143 and a stator vane 183, and an axial interval between a rotor vane 144 and a stator vane 184 are similarly set so that the gas can be dealt with as the molecular flow (these vanes 142 to 144 and 182 to 184 are described later).

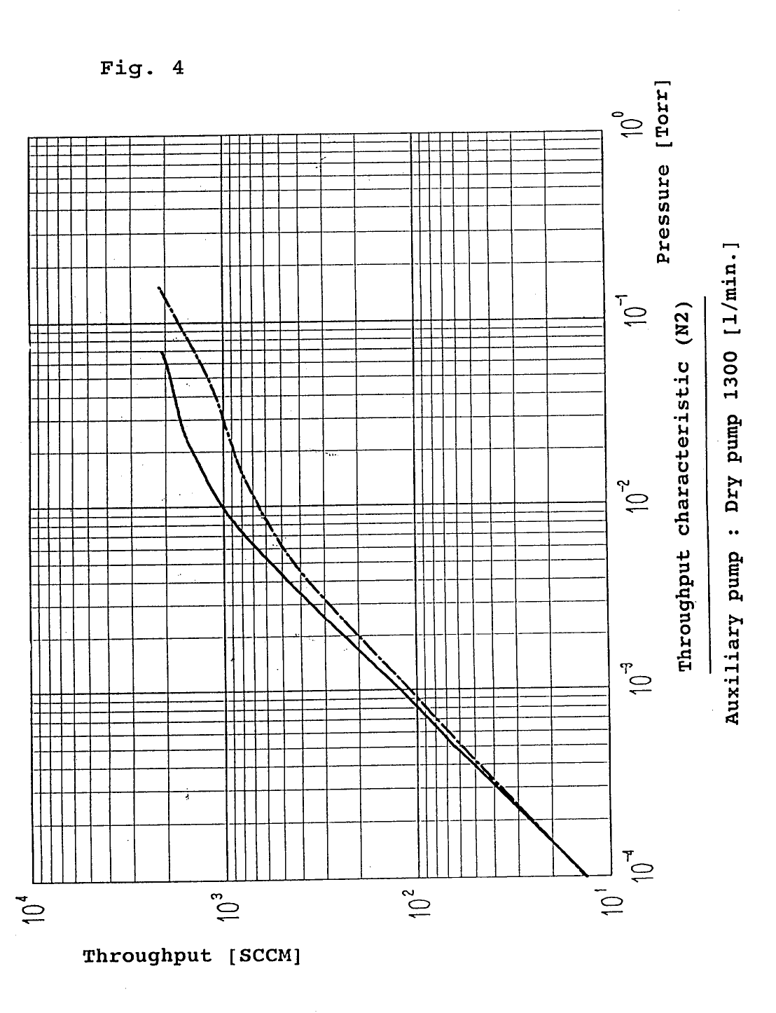

Next, a preferred embodiment of the present invention is described with reference to FIG. 3.

FIG. 3 is a sectional view showing the entire configuration of a turbo molecular pump according to the embodiment of the present invention.

The turbo molecular pump 10 of the embodiment includes, as shown in FIG. 3, a substantially cylindrical rotor shaft 12, a rotor vane section 14 attached to the rotor shaft 12, a stator vane section 18 fixed by a substantially sleeve-like outer casing 16, a magnetic bearing 20 magnetically supporting the rotor shaft 12, and a motor 21 generating torque for the rotor shaft 12.

The rotor vane section 14 includes a substantially sleeve-like body 14a attached to the rotor shaft 12, and four kinds of rotor vanes 141, 142, 143 and 144 attached to the outer periphery of the cylindrical body 14a.

The stator vane section 18 includes four kinds of stator vanes 181, 182, 183 and 184 fixed to the inner periphery of the outer casing 16 so as to correspond to the rotor vanes 141, 142, 143 and 144, respectively.

As shown in FIG. 2, the rotor vane 141 is constructed by a plurality of blades 141a each inclined at a predetermined angle with respect to the rotor shaft 12 and attached to the outer periphery of the cylindrical body 14a to radially extend therefrom.

Each of the rotor vanes 142, 143 and 144 is constructed by a plurality of blades integrally formed at the outer periphery of the cylindrical body 14a similarly to the rotor vane 141, but the blades are different in size and inclined angle among the rotor vanes 142, 143 and 144.

As shown in FIG. 2, the stator vane 181 is constructed by a plurality of blades 181a each inclined in the direction opposite from the inclined direction of the blades 141a of the rotor vane 141.

Each of the stator vanes 182, 183 and 184 is constructed by a plurality of blades similarly to the stator vane 181, but the blades are different in size and inclined angle among the stator vanes 182, 183 and 184.

The thus constructed rotor vanes 141 to 144 and corresponding stator vanes 181 to 184 are arranged alternately in a vertical direction with axial interval one from another.

Each of the axial interval between the rotor vane 141 and the stator vane 181, the axial interval between the rotor vane 142 and the stator vane 182 and the axial interval between the rotor vane 143 and the stator vane 183 is set to 2.5 mm so that the gas under the condition of pressure of not more than 20 mTorr can be dealt as the molecular flow as described above.

With the above-described arrangement, the rotor vane 141 and the stator vane 181 form a discharge stage, the rotor vanes 142, 143 and the stator vanes 182, 183 form an intermediate stage, and the rotor vane 144 and the stator vane 184 form a compression stage.

The above-described magnetic bearing 20 includes radial electromagnets 22, 24 and an axial electromagnet 26 for respectively generating the radial magnetic force and the axial magnetic force with respect to the rotor shaft 12, radial position sensors 30, 32 and an axial position sensor 34 for respectively detecting a radial position and an axial position of the rotor shaft 12, and a control system 36 for feed-back controlling excitation currents supplied to the radial electromagnets 22, 24, and the axial electromagnet 26 based on the detection signals from the radial position sensors 30, 32 and the axial position sensor 34.

Next, the operation of the turbo molecular pump constructed according to the embodiment is described with reference to the drawings.

During the state where the turbo molecular pump is in operation, the rotor shaft 12 is held at a predetermined floating position by the magnetic bearing 20 in a non-contact relation thereto, and the motor 21 is driven to rotate the rotor shaft 12.

The rotation of each of the rotor vanes 141 to 144 between the stator vanes 181 to 184 causes the gas to be sucked through the inlet port 38, compressed, and discharged out of a outlet port 39 as shown in FIG. 3.

In this embodiment, since the gas flow can be dealt as the molecular flow in the discharge stage formed by the rotor vane 141 and the stator vane 181 and the intermediate stage formed by the rotor vanes 142, 143 and the stator vanes 182, 183, the molecular in the gas is beaten by the blades of the rotor vanes 141, 142 and 143, and thus moved toward the outlet port 39.

The test in throughput characteristic was conducted on the embodiment of the present invention similarly to the conventional apparatus, and the test result indicated by the solid line B in FIG. 4 was obtained.

Here, the axial interval between the rotor vane 141 and the stator vane 181 was set to 2.5 mm in case of the embodiment of the present invention, and it was set to 5 mm in case of the conventional apparatus.

From the test result, it was found out, for example, that if the throughput was 1000 SCCM, the pressure in case of the conventional apparatus was 30 mTorr exceeding the required pressure 20 mTorr, but the pressure in case of the embodiment was 10 mTorr. Thus, the embodiment of the present invention could ensure sufficiently required low pressure. Further, if the throughput was 1500 SCCM, the pressure in case of the conventional apparatus was not less than 60 mTorr, but the pressure in case of the embodiment was 20 mTorr. Thus, the embodiment of the present invention could ensure sufficiently required low pressure.

As described above, even if the discharge throughput is increased compared with the conventional throughput, the embodiment of the present invention can ensure the required pressure of 10-20 mTorr (required vacuum property) while maintaining the increased discharge throughput.

This is caused by the above-described setting of the axial interval between the rotor vane 141 and the stator vane 181 and so on so that the gas flow can be regarded as the molecular flow in the axial 3 between the rotor vane 141 and the stator vane 181 and so on.

In addition, in the above embodiment, each of the axial interval between the rotor vane 141 and the stator vane 181, the axial interval between the rotor vane 142 and the stator vane 182, and the axial interval between the rotor vane 143 and the stator vane 183 is set to 2.5 mm so that the gas can be dealt as the molecular flow under the condition of pressure equal to or less than 20 mTorr.

As described above, according to the present invention, the axial interval between the stator vane and the rotor vane is set to such a value as to be capable of dealing with the gas as the molecular flow under the condition that the pressure in the inlet port is equal to or more than 10 mTorr during the normal operation.

Therefore, according to the present invention, the gas can be dealt as the molecular flow under the condition that the pressure is equal to or more than 10 mTorr during the normal operation, and sufficient discharge performance can be obtained. Thus, even if the throughput of the gas supplied to the vacuum chamber during the normal operation is increased compared with the conventional throughput, the present invention can ensure the required pressure (required vacuum property) while maintaining the increased throughput of the gas.

What is claimed is:

1. A turbo molecular pump comprising:
a rotor shaft;
a bearing for rotatably supporting said rotor shaft;
a motor for rotating said rotor shaft supported by said bearing;
rotor vanes of multiple stages provided to said rotor shaft; and
stator vanes of multiple stages arranged between said rotor vanes of multiple stages, respectively,
wherein an axial interval between at least one of said rotor vanes and a corresponding one of said stator vane is set to a value by which a gas can be dealt as a molecular flow under a condition of pressure not less than 10 mTorr during a normal operation.

2. A turbo molecular pump comprising:
a rotor shaft;
a bearing for rotatably supporting said rotor shaft;
a motor for rotating said rotor shaft supported by said bearing;
rotor vanes of multiple stages provided to said rotor shaft; and
stator vanes of multiple stages arranged between said rotor vanes of multiple stages, respectively,
wherein at least one axial interval between one of said rotor vanes and a corresponding one of said stator vane is set to a value by which a gas can be dealt as a molecular flow under a condition that a discharge throughput during a normal operation is not less than 1000 SCCM.

3. A turbo molecular pump according to claim 1 or 2, wherein said one of stator rotor vane is located closest to a inlet port among said rotor vanes of multiple stages, and said corresponding one of said stator vane is located closest to said inlet port among said stator vanes of multiple stages.

4. A turbo molecular pump according to claim 1 or claim 2 wherein said at least one axial interval between one of said rotor vanes and a corresponding one of said stator vane is set based on a mean free path of molecular gas.
